(19) United States
(12) Patent Application Publication
(10) Pub. No.: US 2022/0106705 A1
(43) Pub. Date: Apr. 7, 2022

(54) WAFER TRANSPORT DEVICE, VAPOR DEPOSITION DEVICE, WAFER TRANSPORT METHOD, AND METHOD FOR MANUFACTURING EPITAXIAL SILICON WAFER

(71) Applicant: SUMCO CORPORATION, Tokyo (JP)

(72) Inventors: Kazuhiro NARAHARA, Tokyo (JP); Masayuki TSUJI, Tokyo (JP); Haku KOMORI, Tokyo (JP)

(73) Assignee: SUMCO CORPORATION, Tokyo (JP)

(21) Appl. No.: 17/417,529

(22) PCT Filed: Sep. 25, 2019
(86) PCT No.: PCT/JP2019/037641

§ 371 Date: Jun. 23, 2021

(30) Foreign Application Priority Data
Dec. 25, 2018 (JP) 2018-241365

(51) Int. Cl. C30B 25/12; H01L 21/687; H01L 21/677; C30B 25/20; C30B 29/06; C23C 16/24; C23C 16/458

(52) U.S. Cl. CPC C30B 25/12; H01L 21/68742; H01L 21/67748; C23C 16/4585; C30B 29/06; C23C 16/24; C30B 25/20

(57) ABSTRACT

A wafer transfer device includes a transport unit and a placement unit for placing a silicon wafer transferred by the transport unit onto a susceptor. The placement unit includes a plurality of lift pins and a relative movement mechanism for relatively moving the plurality of lift pins and the susceptor. At least one of the transport unit or the placement unit is configured to bring a predetermined lift pin into the first contact with a lower side of the silicon wafer when the silicon wafer is supported by the plurality of lift pins.

### TECHNICAL FIELD

The present invention relates to a wafer transfer device, a vapor deposition apparatus, a wafer transfer method and a manufacturing method of an epitaxial silicon wafer.

### BACKGROUND ART

In a vapor deposition apparatus, when a wafer is placed on a susceptor, the wafer, whose lower side is supported by a transfer blade, is initially loaded to a position above the susceptor. Then, lift pins are raised to support the lower side of the wafer with upper ends of the lift pins and the wafer is separated from the transfer blade. Subsequently, the lift pins of the vapor deposition apparatus are lowered to place the wafer on the susceptor.

The susceptor is provided with through holes for the lift pins to be inserted. The through holes are designed to provide a certain clearance against d the respective lift pins in order to achieve smooth up-down movement of the lift pins. Accordingly, the lift pins are possibly inclined upon being contacted with the wafer. When the wafer is received from the transfer blade and placed on the susceptor while the lift pins are inclined, the placement position of the wafer may be deviated from a desired position.

Studies have thus been made in order to reduce such deviation of the placement position (see, for instance, Patent Literature 1).

Patent Literature 1 discloses a vapor deposition apparatus including three lift pins and a support ring holding lower end parts of the lift pins to restrain wobble motion of the lift pins. The support ring, which includes a ring portion and plate members whose first longitudinal ends are connected to an inner circumferential surface of the ring portion and whose second longitudinal ends are biased toward the ring portion, is configured to hold the lift pins between the respective plate members and the ring portion.

### CITATION LIST

### Patent Literatures

Patent Literature 1: JP 2017-135147 A

### SUMMARY OF THE INVENTION

### Problems to be Solved by the Invention

However, the lift pins and/or the support ring of Patent Literature 1 are possibly expanded or contracted in response to an increase or a decrease in temperature to cause friction between the lift pins and the support ring. The friction thus caused generates dust from the lift pins and/or the support ring, thereby increasing particles on a resultant epitaxial silicon wafer.

An object of the invention is to provide a wafer transfer device, a vapor deposition apparatus, a wafer transfer method, and a manufacturing method of an epitaxial silicon wafer, which are capable of placing the silicon wafer at a desired position on the susceptor to restrain deterioration in quality of the epitaxial silicon wafer.

### Means for Solving the Problems

A wafer transfer device according to an aspect of the invention is configured to transfer a silicon wafer onto a susceptor of a vapor deposition apparatus configured to form an epitaxial film on the silicon wafer, the wafer transfer device including: a transport unit configured to hold the silicon wafer and transfer the silicon wafer to a position above the susceptor; and a placement unit configured to place the silicon wafer transferred by the transport unit onto the susceptor, in which the placement unit includes: a plurality of lift pins that are received correspondingly one-to-one in a plurality of through holes provided in the susceptor and that are configured to move vertically; and a relative movement mechanism configured to relatively move the plurality of lift pins and the susceptor, the relative movement mechanism is configured to raise the plurality of lift pins relative to the susceptor to support a lower side of the silicon wafer with the plurality of lift pins, and to lower the plurality of lift pins relative to the susceptor to place the silicon wafer onto the susceptor after the silicon wafer is released from the transport unit, and at least one of the transport unit or the placement unit is configured to bring a predetermined lift pin of the plurality of lift pins into a first contact with the lower side of the silicon wafer when the silicon wafer is to be supported by the plurality of lift pins.

When only unprescribed one of the lift pins is brought into the first contact with the silicon wafer when the silicon wafer is to be supported by the plurality of lift pins, the unprescribed one of the lift pins inclines so that the upper end of the unprescribed one of the lift pins moves in a specific direction from the center of the susceptor to the through hole in which the unprescribed one of the lift pins is received due to a clearance between the through hole of the susceptor and the lift pin. If all of the plurality of lift pins are raised relative to the susceptor in this state to receive the silicon wafer from the transport unit and the silicon wafer is subsequently placed on the susceptor by lowering the plurality of lift pins relative to the susceptor, the placement position is deviated in the specific direction with respect to the point right below the loading stop position of the silicon wafer by the transport unit.

According to the above aspect of the invention, since the specific one of the lift pins is brought into the first contact with the silicon wafer, the placement position of the silicon wafer on the susceptor deviates in the above specific direction with respect to the position right below the loading stop position of the silicon wafer by the transport unit. The silicon wafer thus can be placed on a desired position by determining the deviation in the specific direction in advance and setting the loading stop position of the silicon wafer transferred by the transport unit at a position deviated in a direction opposite the specific direction by the above determined deviation. Further, since no special component such as the support ring disclosed in Patent Literature 1 is used, the generation of dust and, consequently, deterioration in the quality of the epitaxial silicon wafer can be restrained.

In the wafer transfer device according to the above aspect of the invention, it is preferable that the relative movement mechanism is configured to raise the plurality of lift pins relative to the susceptor when an upper end of the predetermined lift pin is located at a position higher than upper ends of other lift pins.

According to the above arrangement, the silicon wafer can be placed at the desired position through a simple process of adjusting the height position of the lift pin(s).

In the wafer transfer device according to the above aspect of the invention, it is preferable that the relative movement mechanism is configured to raise the plurality of lift pins relative to the susceptor while the upper end of the predetermined lift pin is located at the level higher than the upper ends of the other lift pins by a height ranging from 0.5 mm to 5 mm.

When the difference in the height positions of the lift pins is less than 0.5 mm, the predetermined lift pin cannot be brought into the first contact with the silicon wafer depending on the magnitude of the warpage due to the heat of the silicon wafer, thereby failing to place the silicon wafer at the desired position. Meanwhile, when the difference exceeds 5 mm, the inclination of the silicon wafer becomes large before the lift pins other than the predetermined lift pin touches the silicon wafer, resulting in great deviation of the silicon wafer on the transport unit and possibly failing to place the silicon wafer at the desired position.

The above arrangement, in which the difference between the height positions of the lift pins is set in the range from 0.5 mm to 5 mm, can restrain occurrence of the above-described disadvantage.

In the wafer transfer device according to the above aspect of the invention, it is preferable that the plurality of lift pins are of the same lengths, the relative movement mechanism includes a lift-pin support member including a plurality of abutment portions contacting respective lower ends of the plurality of lift pins, the lift-pin support member being configured to move relative to the susceptor, and an upper end of one of the abutment portions contacting the predetermined lift pin is located at a position higher than upper ends of the other abutment portions.

According to the above arrangement, the silicon wafer can be placed at the desired position through a simple process of locating the upper end of the specific abutment portion at a position higher than the upper ends of the other abutment portions.

In the wafer transfer device according to the above aspect of the invention, it is preferable that the predetermined lift pin is longer than the other lift pins, the relative movement mechanism includes a lift-pin support member including a plurality of abutment portions contacting respective lower ends of the plurality of lift pins, the lift-pin support member being configured to move relative to the susceptor, and the upper ends of the plurality of abutment portions are located at the same height position.

According to the above arrangement, the silicon wafer can be placed at the desired position through a simple process of lengthening the predetermined lift pin than other lift pins.

In the wafer transfer device according to the above aspect of the invention, it is preferable that at the position above the susceptor, the transport unit is configured to transfer the silicon wafer so that a part of the silicon wafer supported by the predetermined lift pin is located lower than the other part of the silicon wafer.

According to the above arrangement, the silicon wafer can be placed at the desired position through a simple process of adjusting the orientation of the silicon wafer transferred by the transport unit at the position above the susceptor.

In the wafer transfer device according to the above aspect of the invention, it is preferable that the transport unit includes an elongated support member and is configured to transfer the silicon wafer at the position above the susceptor by moving the support member, on which the silicon wafer is mounted, in a longitudinal direction of the support member, the support member includes a pair of extensions extending from mutually remote positions in the longitudinal direction of the support member, and the relative movement mechanism is configured bring one of the plurality of lift pins located between the pair of extensions as the predetermined lift pin into the first contact with the lower side of the silicon wafer.

When the silicon wafer is transferred onto the susceptor, the silicon wafer sometimes warps so that the lower side protrudes downwardly or the upper side protrudes upwardly due to the heat inside a chamber housing the susceptor.

According to the above arrangement, even the silicon wafer having an unstable warpage can be placed on the target placement position.

A vapor deposition apparatus according to another aspect of the invention is configured to form an epitaxial film on a silicon wafer, the vapor deposition apparatus including: a susceptor, on which the silicon wafer is configured to be placed; and the above-described wafer transfer device being configured to transfer the silicon wafer onto the susceptor.

A wafer transfer method according to still another aspect of the invention is for transferring a silicon wafer onto a susceptor of a vapor deposition apparatus configured to form an epitaxial film on the silicon wafer, the wafer transfer method including: loading step of holding the silicon wafer and transferring the silicon wafer to a position above the susceptor; and placing step of placing the silicon wafer transferred in the loading step onto the susceptor, in which the placing step includes a relative movement step of raising a plurality of lift pins, which are vertically movably inserted correspondingly one-to-one into a plurality of through holes penetrating through the susceptor, relative to the susceptor to support a lower side of the silicon wafer at the position above the susceptor, and lowering the plurality of lift pins relative to the susceptor to place the silicon wafer onto the susceptor after the silicon wafer is released from the holding in the loading step, and, and at least one of the loading step or the placing step includes bringing a predetermined lift pin of the plurality of lift pins into a first contact with the lower side of the silicon wafer when the silicon wafer is supported by the plurality of lift pins.

In the wafer transfer method according the above aspect of the invention, it is preferable that a support member, which extends in a longitudinal direction and includes a pair of extensions extending from mutually remote positions in the longitudinal direction of the support member, is used, the silicon wafer is of p-type, the loading step includes moving the support member carrying the p-type silicon wafer in the longitudinal direction to transfer the p-type silicon wafer to the position above the susceptor, and in the relative movement step, one of the plurality of lift pins located between the pair of extensions as the predetermined lift pin is brought into the first contact with the lower side of the silicon wafer.

A manufacturing method according to further aspect of the invention is for manufacturing an epitaxial silicon wafer including an epitaxial film formed on a silicon wafer, the manufacturing method including: performing the above-described wafer transfer method for transferring the silicon wafer onto the susceptor; and vapor-phase growing the epitaxial film on the silicon wafer transferred by the susceptor.

### BRIEF DESCRIPTION OF THE DRAWINGS

FIG. 1 is a schematic illustration of a vapor deposition apparatus according to an exemplary embodiment of the invention, as viewed in a first direction.

FIG. 2 is a schematic illustration of the vapor deposition apparatus as viewed in a second direction orthogonal to the first direction.

FIG. 3 is a perspective view of a susceptor and a susceptor support member of the vapor deposition apparatus.

FIG. 4 is a cross sectional view of a through hole of the susceptor.

FIG. 5 is a schematic illustration showing how lift pins of the vapor deposition apparatus are supported by a lift-pin support member.

FIG. 6A, which illustrates a manufacturing method of an epitaxial silicon wafer using the vapor deposition apparatus, is a plan view showing a silicon wafer transferred to a position above the susceptor.

FIG. 6B, which illustrates the manufacturing method of the epitaxial silicon wafer using the vapor deposition apparatus, is a lateral elevational view showing the silicon wafer in contact with the lift pin.

FIG. 6C, which illustrates the manufacturing method of the epitaxial silicon wafer using the vapor deposition apparatus, is a plan view showing the silicon wafer placed on the susceptor.

FIG. 7A, which illustrates the manufacturing method of the epitaxial silicon wafer, is a lateral elevational view showing a warped p++ type or p-type silicon wafer in contact with the lift pin.

FIG. 7B, which illustrates the manufacturing method of the epitaxial silicon wafer, is a lateral elevational view showing a warped p-type silicon wafer in contact with the lift pin.

FIG. 8A is a lateral elevational view showing a silicon wafer in contact with a lift pin according to a modification of the invention.

FIG. 8B is a lateral elevational view showing a silicon wafer in contact with a lift pin according to another modification.

FIG. 9A shows distribution of placement positions of silicon wafers with respect to a target placement position according to Comparative of the invention.

FIG. 9B shows distribution of placement positions of silicon wafers with respect to the target placement position according to Example 1 of the invention.

FIG. 9C shows distribution of placement positions of silicon wafers with respect to the target placement position according to Example 2 of the invention.

FIG. 10A shows distribution of the placement positions of the silicon wafers with respect to the target placement position according to Example 1 after adjusting a loading stop position on a basis of results shown in FIG. 9B.

FIG. 10B shows distribution of the placement positions of the silicon wafers with respect to the target placement position according to Example 2 after adjusting the loading stop position on a basis of results shown in FIG. 9C.

### DESCRIPTION OF EMBODIMENT(S)

### Exemplary Embodiment(s)

An exemplary embodiment of the invention will be described below.

### Arrangement of Vapor Deposition Apparatus

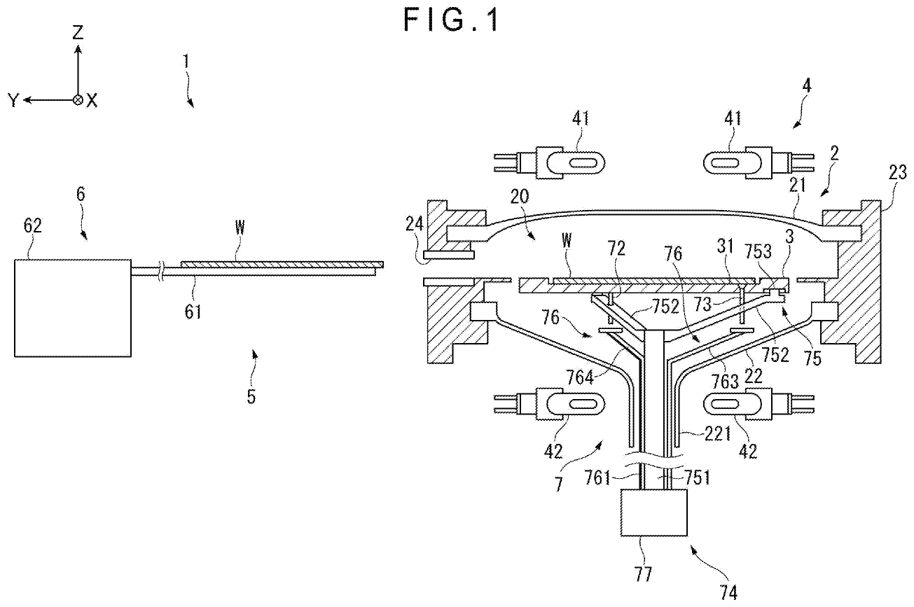

As shown in FIG. 1, a vapor deposition apparatus 1 includes a chamber 2, a susceptor 3, a heater 4, and a wafer transfer device 5.

The chamber 2 includes an upper dome 21, a lower dome 22, and a dome fixing member 23 for fixing outer peripheries of the domes 21, 22, the domes 21, 22 and the dome fixing member 23 defining an epitaxial-film formation chamber 20.

The upper dome 21 and the lower dome 22 are made of quartz.

A tubular portion 221, which extends downward and is configured to receive a later-described main shaft 761 of a lift-pin support member 76, is provided at the center of the lower dome 22. The dome fixing member 23 is provided with a wafer loading-unloading opening 24 for loading or unloading a silicon wafer W into or out of the epitaxial-film formation chamber 20.

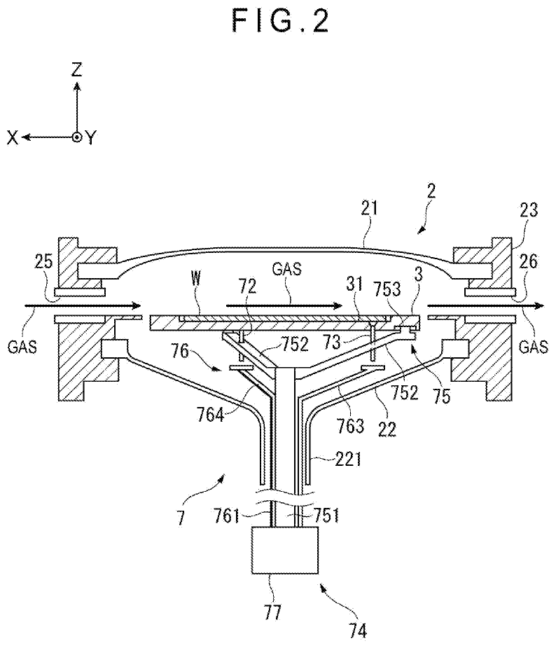

As shown in FIG. 2, the dome fixing member 23 includes a gas inlet 25 for supplying gas into the epitaxial-film formation chamber 20 and a gas outlet 26 for discharging the gas out of the epitaxial-film formation chamber 20.

The susceptor 3 is a disc-shaped carbon component covered with silicon carbide.

A disc-shaped countersink 31 configured to receive the silicon wafer W is provided on a first principal surface of the susceptor 3. The diameter of the countersink 31 is larger than the diameter of the silicon wafer W.

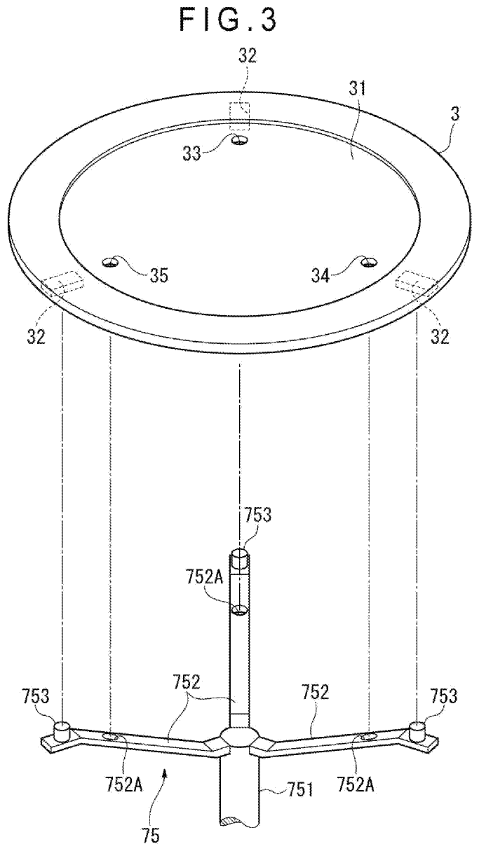

As shown in FIG. 3, three fitting grooves 32, in which later-described support pins 753 are fitted, are provided near an outer periphery of a second principal surface of the susceptor 3. The fitting grooves 32 are provided at intervals of 120 degrees in a circumferential direction of the susceptor 3.

The susceptor 3 is further provided with first, second and third through holes 33, 34, 35 penetrating both principal surfaces.

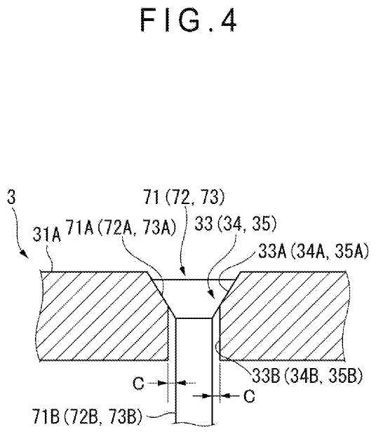

The through holes 33, 34, 35 are provided in the countersink 31 at intervals of 120 degrees in the circumferential direction of the susceptor 3. As shown in FIG. 4, the through holes 33, 34, 35 respectively include conical tapered portions 33A, 34A, 35A whose inner diameter decreases from a placement surface 31A of the countersink 31, in which the silicon wafer W is placed, to the center in the thickness direction of the susceptor 3, and shaft holes 33B, 34B, 35B whose inner diameters are constant in the thickness direction of the susceptor 3.

As shown in FIG. 1, the heater 4 includes an upper heater 41 and a lower heater 42 provided on an upper side and a lower side of the chamber 2, respectively. The upper heater 41 and the lower heater 42 are each provided by an infrared lamp, halogen lamp, or the like.

The wafer transfer device 5 is configured to transfer the silicon wafer W onto the susceptor 3. The wafer transfer device 5 includes a transport unit 6 and a placement unit 7.

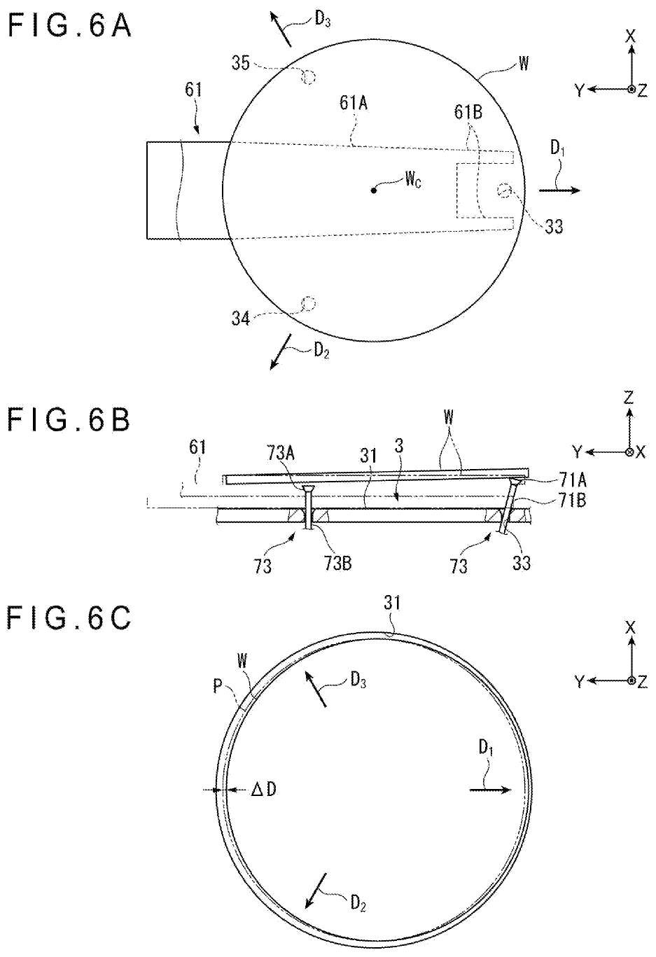

The transport unit 6 is configured to hold the silicon wafer W and transfer the silicon wafer W onto the susceptor 3. The transport unit 6 includes a longitudinal support member 61 (see FIG. 6A) and a transfer robot 62.

The support member 61 is a thin elongated rectangular plate component made of, for instance, quartz. The support member 61 includes a thin elongated rectangular plate-shaped body 61A and a pair of extensions 61B provided at an end of the body 61A, the extensions 61B extending from respective widthwise ends of the body 61A.

The transfer robot 62 holds a longitudinal end of the support member 61. The transfer robot 62 moves the support member 61 in the longitudinal direction thereof to transfer the silicon wafer W placed on the support member 61 into the chamber 2. After the silicon wafer W is placed on the countersink 31 of the susceptor 3, the transfer robot 62 moves the support member 61 back to its original position. As necessary, the transfer robot 62 moves the support member 61 in a direction orthogonal to the longitudinal direction before the silicon wafer W is transferred into the chamber 2 to adjust the placement position of the silicon wafer W on the susceptor 3.

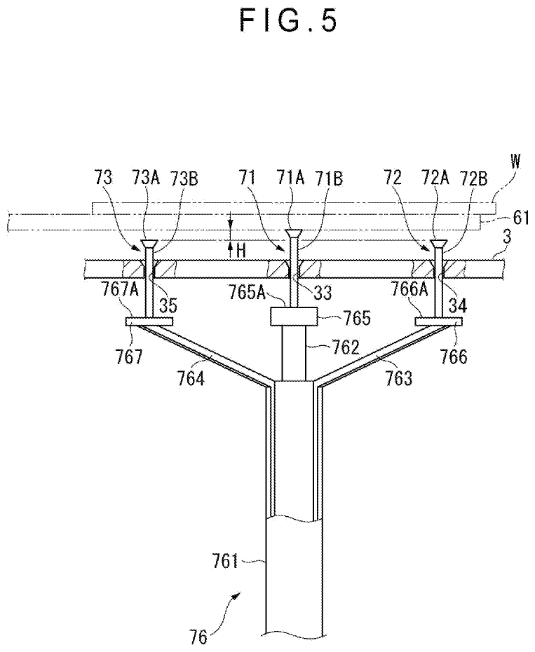

The placement unit 7 is configured to place the silicon wafer W transferred by the transport unit 6 onto the susceptor 3. As shown in FIGS. 1, 2, 3, and 5, the placement unit 7 includes first, second and third lift pins 71, 72, 73 and a relative movement mechanism 74.

The lift pins 71, 72 73 are formed in the same shape as a stick-shaped component made of, for instance, carbon covered with silicon carbide. As shown in FIG. 4, the lift pins 71, 72, 73 respectively include truncated conical heads 71A, 72A, 73A and cylindrical shafts 71B, 72B, 73B extending from respective small-diameter ends of the heads 71A, 72A, 73A.

The shafts 71B, 72B, 73B of the lift pins 71, 72, 73 are inserted into the respective shaft holes 33B, 34B, 35B of the through holes 33, 34, 35 and the heads 71A, 72A, 73A are brought into contact with the tapered portions 33A, 34A, 35A due to the weight of the lift pins 71, 72, 73, respectively, so that the lift pins 71, 72, 73 are supported by the susceptor 3. It is preferable that the heads 71A, 72A, 73A are formed so that upper ends of the heads 71A, 72A, 73A are located below the placement surface 31A of the countersink 31 when the lift pins 71, 72, 73 are supported by the susceptor 3. The shafts 71B, 72B, 73B are each formed to have a thickness providing a clearance C against the respective shaft holes 33B, 34B, 35B when the center axes of the shafts 71B, 72B, 73B are aligned with the respective center axes of the shaft holes 33B, 34B, 35B of the through holes 33, 34, 35.

The relative movement mechanism 74 is configured to relatively move the lift pins 71, 72, 73 and the susceptor 3 to place the silicon wafer W transferred by the transport unit 6 onto the susceptor 3. The relative movement mechanism 74 includes a susceptor support member 75, a lift-pin support member 76, and a drive unit 77.

The susceptor support member 75 is made of quartz. The susceptor support member 75 includes a cylindrical main shaft 751, three arms 752 extending radially from an end of the main shaft 751, and support pins 753 provided at respective ends of the arms 752.

The arms 752, which extend diagonally upward, are provided at intervals of 120 degrees in a circumferential direction of the main shaft 751. Through holes 752A penetrating through the respective arms 752 are provided at a longitudinal center of each of the arms 752.

The support pins 753, which are made of solid SiC, are fitted to respective fitting grooves 32 of the susceptor 3 to support the susceptor 3.

The lift-pin support member 76 are made of quartz. The lift-pin support member 76 includes: a cylindrical main shaft 761; first, second, and third arms 762, 763, 764 extending radially from an end of the main shaft 761; and abutment portions 765, 766, 767 provided at respective ends of the arms 762, 763, 764.

The arms 762, 763, 764, which extend diagonally upward, are provided at intervals of 120 degrees in a circumferential direction of the main shaft 761.

The abutment portions 765, 766, 767 support the lift pins 71, 72, 73 from below with upper end surfaces 765A, 766A, 767A thereof, respectively. The first abutment portion 765 is situated higher than the second and third abutment portions 766, 767. A difference ΔH between the height of the upper end surface 765A and the height of the upper end surfaces 766A, 767A is preferably in a range from 0.5 mm to 5 mm, more preferably in a range from 2 mm to 3 mm.

The main shaft 761 is received in the tubular portion 221 of the lower dome 22 in a state where the arms 762, 763, 764 are located inside the epitaxial-film formation chamber 20.

The main shaft 751 is received within the main shaft 761 in a state where the arms 762, 763, 764 are located below the arms 752 of the susceptor support member 75 and lower ends of the lift pins 71, 72, 73 supported by the susceptor 3 are capable of being in contact with the respective upper end surfaces 765A, 766A, 767A of the abutment portions 765, 766, 767.

The drive unit 77 is configured to rotate the susceptor support member 75 and the lift-pin support member 76 and vertically move the lift-pin support member 76.

### Manufacturing Method of Epitaxial Silicon Wafer

Next, a manufacturing method of an epitaxial silicon wafer using the vapor deposition apparatus 1 will be described below.

Initially, a p type or n type silicon wafer W is prepared. The p type silicon wafer W contains boron. The n type silicon wafer contains phosphorus, arsenic, and/or antimony. The diameter of the silicon wafer W may be determined as desired (e.g. 200 mm, 300 mm, 450 mm or the like).

Next, the support member 61 of the transport unit 6, which is installed in a robot chamber (not shown) in nitrogen atmosphere, supports the silicon wafer W so that the principal surfaces of the silicon wafer W are in parallel with a horizontal surface. Subsequently, after a gate valve (not shown) provided between the robot chamber and the chamber 2 is opened, while the principal surfaces are kept parallel with the horizontal surface, the transfer robot 62 of the transport unit 6 transfers the silicon wafer W through the wafer loading-unloading opening 24 into the epitaxial-film formation chamber 20 heated by the heater 4. The silicon wafer W is stopped at a position above the countersink 31 of the susceptor 3.

At this time, as shown in FIG. 6A, the orientation of the susceptor 3 in a rotation direction is adjusted so that the first through hole 33 is located in the middle of the pair of extensions 61B and at a loading side with respect to the center W_{c} of the silicon wafer W, and the second and third through holes 34, 35 are located outside the body 61A and at an unloading side with respect to the center W_{c} (i.e. near the robot chamber).

Subsequently, the drive unit 77 of the wafer transfer device 5 raises the lift-pin support member 76 to raise the lift pins 71, 72, 73 supported by the susceptor 3. At this time, since the upper end surface 765A of the first abutment portion 765 is located higher than the upper end surfaces 766A, 767A of the second and third abutment portions 766, 767, the lift pins 71, 72, 73 rise with the head 71A of the first lift pin 71 being kept higher than the heads 72A, 73A of the second and third lift pins 72, 73. Accordingly, the first lift pin 71 is initially brought into contact with the lower side of the silicon wafer W, succeeded by the second and third lift pins 72, 73.

If the abutment portions 765, 766, 767 of the lift-pin support member 76 are of the same height, the heads 71A, 72A, 73A of the lift pin 71, 72, 73 rise while being kept at the same height. The silicon wafer W, which is heated by the heater 4 in the epitaxial-film formation chamber 20, warps due to a difference between the principal surfaces in terms of the temperature and heat absorption. In this case, depending on the warpage of the silicon wafer W, the lift pin that is initially brought into contact with the silicon wafer W may be the first lift pin 71, the second lift pin 72, or the like, which is not stable.

The shaft holes 33B, 34B, 35B of the through holes 33, 34, 35 of the susceptor 3 are formed to provide the clearance C against the respective shafts 71B, 72B, 73B of the lift pins 71, 72, 73. Accordingly, when, for instance, the first lift pin 71 is brought into the first contact with the silicon wafer W (shown in chain double-dashed lines in FIG. 6B) and then further rises, the weight of the silicon wafer W acts solely on the first lift pin 71 while the lower end of the first lift pin 71 is not fixed by the first abutment portion 765, the first lift pin 71 is inclined due to the presence of the clearance C. Specifically, the first lift pin 71 is inclined so that the head 71A is displaced in a first direction D₁ (i.e. a direction from the center of the susceptor 3 to the first through hole 33).

The inclination of the first lift pin 71 causes the silicon wafer W to be deviated in the first direction D₁ with respect to the stop position on the susceptor 3 by the transport unit 6 as shown in solid lines in FIG. 6B.

When the lift-pin support member 76 is further raised in this state, all of the lift pins 71, 72, 73 are brought into contact with the silicon wafer W to lift the silicon wafer W off the support member 61. However, the position of the lifted silicon wafer W is deviated in the first direction D₁ with respect to the stop position of the susceptor 3.

When the transport unit 6 moves the support member 61 out of the chamber 2 and the gate valve is closed, the drive unit 77 lowers the lift-pin support member 76 to place the silicon wafer W in the countersink 31 of the susceptor 3. However, the placement position of the silicon wafer W is kept deviated in the first direction D₁ with respect to a target placement position P on the susceptor 3 as shown in FIG. 6C.

The deviation of the placement position of the silicon wafer W similarly occurs when the second lift pin 72 and the third lift pin 73 are brought into the first contact with the silicon wafer W. The deviation direction is a second direction D₂ from the center of the susceptor 3 to the second through hole 34 when the second lift pin 72 is brought into first contact, and a third direction D₃ from the center of the susceptor 3 to the third through hole 35 when the third lift pin 73 is brought into first contact, as shown in FIG. 6A.

If the lift pins 71, 72, 73 are raised with the heads 71A, 72A, 73A being kept at the same level, it is unpredictable in which direction the placement position of the silicon wafer W on the susceptor 3 would be deviated.

In contrast, since the first lift pin 71 is brought into the first contact with the lower side of the silicon wafer W in the exemplary embodiment, the silicon wafer W is deviated only in the first direction D₁ when all of the lift pins 71, 72, 73 are in contact with the silicon wafer W.

The stop position of the silicon wafer W after being transferred by the transport unit 6 is generally right above the target placement position P of the silicon wafer W on the susceptor 3. However, in the first exemplary embodiment, it is expected that the stop position of the silicon wafer W is highly likely to be deviated in the first direction D₁ with respect to the placement position.

Accordingly, the silicon wafer W can be placed on the target placement position P on the susceptor 3 by determining the deviation ΔD in advance and setting the stop position of the silicon wafer W to be transferred by the transport unit 6 at a position retreated by ΔD from the position right above the target placement position P in a direction opposite the first direction D₁.

Further, when the silicon wafer W is supported by the support member 61 on the susceptor 3, the temperature of the lower side of the silicon wafer W is higher than the temperature of the upper side due to radiation heat from the susceptor 3.

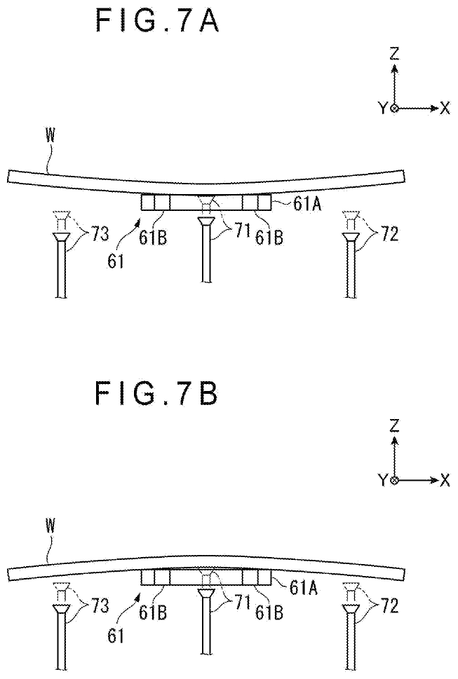

Especially, when being of p++ type, the silicon wafer W has a high heat absorption rate and thus tends to exhibit larger temperature difference between the upper and lower sides of the silicon wafer W due to an influence of the radiation heat. Accordingly, when being loaded onto the susceptor 3, the silicon wafer W warps in a short time with the lower side protruding downwardly as shown in FIG. 7A. In other words, the silicon wafer W warps with a part present between the pair of extensions 61B of the support member 61 becoming lower than parts located outside the body 61A. Accordingly, the first lift pin 71, which is present between the pair of extensions 61B as shown in chain double-dashed lines in FIG. 7A, is likely to be brought into the first contact with the silicon wafer W.

In contrast, when being of p-type, the silicon wafer W, which has lower heat absorption rate than that of p++ type, is less likely to exhibit temperature difference between the upper and lower sides of the silicon wafer W due to the radiation heat. Accordingly, when being loaded onto the susceptor 3, the silicon wafer W warps so that the lower side protrudes downwardly as shown in FIG. 7A or the upper side protrudes upwardly as shown in FIG. 7B. In other words, the silicon wafer W warps so that a part present between the pair of extensions 61B is lower or higher than parts located outside the body 61A.

When the silicon wafer W warps as shown in FIG. 7A, the first lift pin 71 is likely to be brought into the first contact with the silicon wafer W as in the p++ type silicon wafer W.

In contrast, when the silicon wafer W warps as shown in FIG. 7B, if the lift pins 71, 72, 73 are at the same height, the second lift pin 72 or the third lift pin 73 located outside the body 61A is likely to be brought into the first contact with the silicon wafer W, and thus it becomes difficult to determine in advance in which direction the placement position would be deviated. Consequently, it sometimes occurs that the silicon wafer W cannot be placed at the target placement position P. However, since the height position of the first lift pin 71 is higher than those of the second and third lift pins 72, 73 in the first exemplary embodiment, by setting the difference between the height position of the first lift pin 71 and the height position of the second and third lift pins 72, 73 to be larger than the warpage of the silicon wafer W, the first lift pin 71 is likely to be brought into the first contact with the silicon wafer W as shown in chain double-dashed lines in FIG. 7B, thereby allowing the direction in which the placement position is deviated to be determined in advance. Consequently, even the p-silicon wafer W with an unstable warpage can be placed at the target placement position P.

It should be noted that the warpage (i.e. the level difference between the outer edge and the center of the silicon wafer W) of the silicon wafer W is, though depending on the thickness of the silicon wafer W and the temperature in the epitaxial-film formation chamber 20, is approximately 1 mm.

After the silicon wafer W is placed on the susceptor 3, hydrogen gas (carrier gas) is continuously supplied through the gas inlet 25 and discharged through the gas outlet 26 to turn the atmosphere within the epitaxial-film formation chamber 20 into a hydrogen atmosphere. Subsequently, after the temperature within the epitaxial-film formation chamber 20 is raised, material gas and dopant gas are supplied into the epitaxial-film formation chamber 20 together with the carrier gas, and the susceptor support member 75 and the lift-pin support member 76 are rotated by the drive unit 77 to form an epitaxial film on the silicon wafer W.

It should be noted that examples of the material gas include SiH₄ (monosilane), SiH₂Cl₂ (dichlorosilane), SiHCl₃ (trichlorosilane), and SiCl₄ (silicon tetrachloride). Examples of the dopant gas include boron compounds such as B₂H₆ (diborane) and BCl₃ (trichloroborane) for a P type epitaxial film and PH₃ (phosphine), AsH₃ (arsine), and the like for an N type epitaxial film.

After the epitaxial film is formed, the drive unit 77 raises the lift-pin support member 76 to lift the silicon wafer W off the susceptor 3 using the lift pins 71, 72, 73. Subsequently, after the gate valve is opened, the transfer robot 62 moves the support member 61 into the epitaxial-film formation chamber 20 and stops the support member 61 at a position below the silicon wafer W. Then, after the drive unit 77 lowers the lift-pin support member 76 to transfer the silicon wafer W onto the support member 61, the transfer robot 62 transfers the support member 61 together with the silicon wafer W out of the epitaxial-film formation chamber 20, thereby terminating a manufacturing process of a single epitaxial silicon wafer.

### Effect of Exemplary Embodiment

According to the above-described exemplary embodiment, since the first lift pin 71 among the lift pins 71, 72, 73 is brought into the first contact with the silicon wafer W, the silicon wafer W can be placed at a desired position by determining in advance the deviation of the placement position of the silicon wafer W in the first direction D₁ and setting the stop position of the silicon wafer W to be transferred by the transport unit 6.

Since the first abutment portion 765 is higher than the second and third abutment portions 766, 767, the silicon wafer W can be placed at the desired position even with the use of the lift pins 71, 72, 73 of the same shape.

Among the lift pins 71, 72, 73, the first lift pin 71 (predetermined lift pin) positioned between the pair of extensions 61B is brought into the first contact with the lower side of the silicon wafer W. Accordingly, even the p-type silicon wafer W having an unstable warpage can be placed at the target placement position P.

### Modifications

It should be noted that the scope of the invention is not limited to the above-described exemplary embodiment but encompasses various improvements and design alterations as long as such improvements and alterations are compatible with an object of the invention.

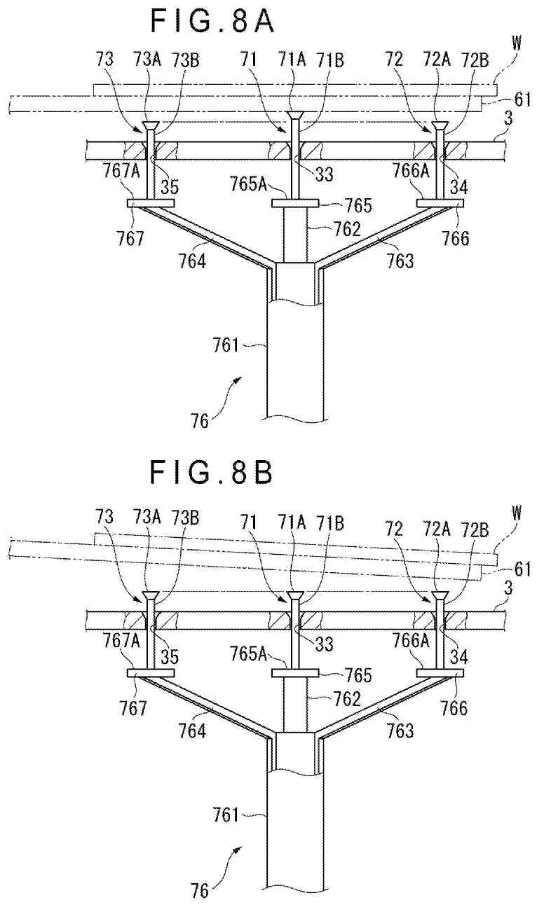

For instance, as shown in FIG. 8A, the heights of the abutment portions 765, 766, 767 are the same and the length of the first lift pin 71 is longer than the lengths of the second and third lift pins 72, 73, so that the first lift pin 71 is brought into the first contact with the silicon wafer W loaded in a manner that the principal surfaces thereof are parallel to the horizontal surface, in some embodiments.

As shown in FIG. 8B, the heights of the abutment portions 765, 766, 767 and the lengths of the lift pins 71, 72, 73 are the same, and the silicon wafer W is loaded by the support member 61 of the transport unit 6 in a manner that the principal surfaces of the silicon wafer W are inclined with respect to the horizontal surface, thereby allowing the first lift pin 71 to be brought into the first contact with the silicon wafer W, in some embodiments.

In the above-described exemplary embodiment and the modifications shown in FIGS. 8A and 8B, the first lift pin 71 is brought into the first contact with the silicon wafer W. However, the second lift pin 72 or the third lift pin 73 is brought into the first contact with the silicon wafer W in some embodiments. Though the placement position of the silicon wafer W is deviated in the second direction D₂ or the third direction D₃ when the second lift pin 72 or the third lift pin 73 is brought into the first contact, the silicon wafer W can be placed at the desired position by moving the support member 61, depending on the deviation direction, in a direction orthogonal to the loading direction of the silicon wafer W before the silicon wafer W is loaded into the epitaxial-film formation chamber 20.

The lift pins 71, 72, 73 are provided after being rotated by 180 degrees in the circumferential direction of the susceptor 3 in some embodiments. The number of the lift pins are four or more in some embodiments.

After the silicon wafer W is received by all of the lift pins 71, 72, 73 from the transport unit 6, the susceptor 3 is raised while the lift pins 71, 72, 73 are stopped or lowered to place the silicon wafer W on the susceptor 3, in some embodiments.

### EXAMPLES

Next, the invention will be described in further detail below with reference to Examples. It should however be noted that the invention is by no means limited by these Examples.

### Comparative

Initially, the same vapor deposition apparatus as that in the above-described exemplary embodiment and a p-type 300-mm-diameter and 775-μm-thick silicon wafer W were prepared. The clearance C between the shafts 71B, 72B, 73B of the prepared lift pins 71, 72, 73 and the respective shaft hole 33B, 34B, 35B of the through holes 33, 34, 35 was 0.25 mm.

Then, the silicon wafer W was placed on the susceptor 3 with the height position of each of the lift pins 71, 72, 73 being at the same level and interior of the epitaxial-film formation chamber 20 being heated to 700 degrees C. The deviation between the center of the silicon wafer W placed on the susceptor 3 and the center of the target placement position P was measured from above the susceptor using a measurement machine (Edge Zoom manufactured by Epicrew Corporation). Similar experiments were performed on one hundred silicon wafers W.

### Example 1

The same experiment as Comparative 1 was performed except that the height position of the first lift pin 71 was higher than the height positions of the second and third lift pins 72, 73 by 1 mm.

### Example 2

The same experiment as Comparative 1 was performed except that the height position of the first lift pin 71 was higher than the height positions of the second and third lift pins 72, 73 by 2 mm.

### Evaluation

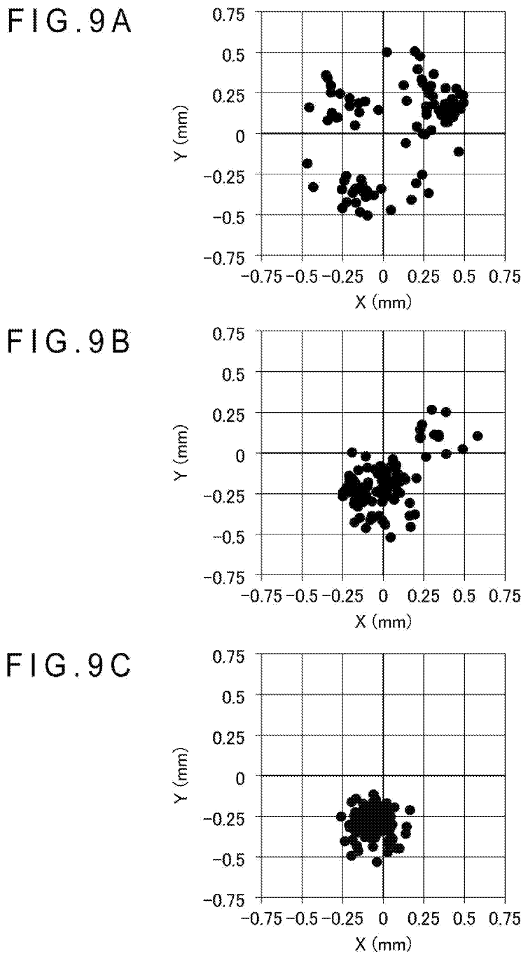

Measurement results of Comparative and Examples 1, 2 are shown in FIGS. 9A, 9B,and 9C.

It should be noted that the values of ordinate axis Y and abscissa axis X in FIGS. 9A, 9B, and 9C are values with reference to XYZ axes in FIGS. 1, 2, 6A to 6C, 7A, and 7B. Specifically, the positive and the negative values of the ordinate axis Y respectively represent the deviations of the silicon wafer W in the unloading direction and the loading direction (first direction D₁). The positive and negative values of the abscissa axis X respectively represent the deviations in one direction orthogonal to the loading direction (third direction D₃) and the other direction (second direction D₂) orthogonal to the loading direction.

Further, the point at which both of the scales of the abscissa and ordinate axes are 0 mm represent that the placement position of the silicon wafer W is not deviated from the target placement position P.

As shown in FIG. 9A, the placement positions in Comparative are deviated variously from the target placement position P in the circumferential direction of the susceptor 3, showing large variations in the deviated positions.

It is believed that this is because the lift pin that is brought into the first contact with the silicon wafer W is not specified since the warpage of the p-type silicon wafer W occurs in the state shown in FIG. 7A or FIG. 7B as described above.

In contrast, as shown in FIG. 9B, the placement positions in Example 1 are concentrated in two specific regions deviated from the target placement position P, showing smaller variations in the deviated positions than those in Comparative.

Further, as shown in FIG. 9C, the placement positions in Example 2 are concentrated in one specific region deviated from the target placement position P, showing further smaller variations in the deviated positions than those in Comparative and Example 1.

It is believed this is because, even for the p-type silicon wafer W whose warpage direction is unstable, a probability for the first lift pin 71 to be brought into the first contact with the silicon wafer W is enhanced by setting the height position of the first lift pin 71 to be higher than those of the second and third lift pins 72, 73, and the probability is increased as the difference between the height positions is increased.

It is also estimated that the variations in the deviations between the target placement position P and the placement position can be further reduced when the difference between the height position of the first lift pin 71 and the height positions of the second and third lift pins 72, 73 exceeds 2 mm.

It is confirmed from the above that the deviations between the placement position and the target placement position P of the silicon wafer W can be reduced by setting the height position of the first lift pin 71 to be higher than the height positions of the second and third lift pins 72, 73.

Especially, it is confirmed that the placement positions of the silicon wafer W can be concentrated in the specific one region when the difference between the height position of the first lift pin 71 and the height positions of the second and third lift pins 72, 73 is 2 mm or more, further reducing the variations in the deviations.

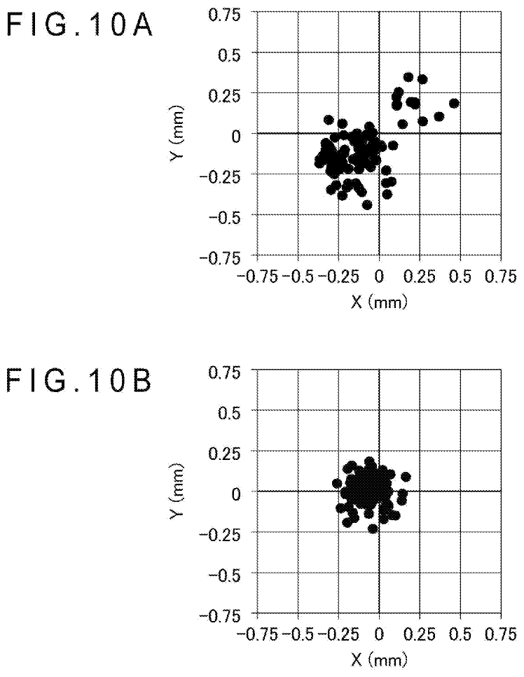

Based on the above results, the silicon wafer W can be placed at a desired position by determining the deviation of the placement position of the silicon wafer W in advance in accordance with the setting conditions of the height position of the lift pins 71, 72, 73 and displacing the loading stop position of the silicon wafer W that is transferred by the transport unit 6 so that the silicon wafer W is placed at, for instance, the position shown in FIG. 10A (under the condition of Example 1) or the position shown in FIG. 10B (under the condition of Example 2).

### Explanation of Codes

1 . . . vapor deposition apparatus, 3 . . . susceptor, 5 . . . wafer transfer device, 6 . . . transport unit, 7 . . . placement unit, 33, 34, 35 . . . through hole, 61 . . . support member, 71, 72, 73 . . . lift pin, 74 . . . relative movement mechanism, 76 . . . lift-pin support member, 765, 766, 767 . . . abutment portion, W . . . silicon wafer

1. A wafer transfer device configured to transfer a silicon wafer onto a susceptor of a vapor deposition apparatus configured to form an epitaxial film on the silicon wafer, the wafer transfer device comprising:
a transport unit configured to hold the silicon wafer and transfer the silicon wafer to a position above the susceptor; and
a placement unit configured to place the silicon wafer transferred by the transport unit onto the susceptor, wherein
the placement unit comprises:
a plurality of lift pins that are received correspondingly one-to-one in a plurality of through holes provided in the susceptor and that are configured to move vertically; and
a relative movement mechanism configured to relatively move the plurality of lift pins and the susceptor,
the relative movement mechanism is configured to raise the plurality of lift pins relative to the susceptor to support a lower side of the silicon wafer with the plurality of lift pins, and to lower the plurality of lift pins relative to the susceptor to place the silicon wafer onto the susceptor after the silicon wafer is released from the transport unit, and
at least one of the transport unit or the placement unit is configured to bring a predetermined lift pin of the plurality of lift pins into a first contact with the lower side of the silicon wafer when the silicon wafer is to be supported by the plurality of lift pins.

2. The wafer transfer device according to claim 1, wherein
the relative movement mechanism is configured to raise the plurality of lift pins relative to the susceptor when an upper end of the predetermined lift pin is located at a position higher than upper ends of other lift pins.

3. The wafer transfer device according to claim 2, wherein
the relative movement mechanism is configured to raise the plurality of lift pins relative to the susceptor while the upper end of the predetermined lift pin is located at the position higher than the upper ends of the other lift pins by a height ranging from 0.5 mm to 5 mm.

4. The wafer transfer device according to claim 2, wherein
the plurality of lift pins are of the same lengths,
the relative movement mechanism comprises a lift-pin support member comprising a plurality of abutment portions contacting respective lower ends of the plurality of lift pins, the lift-pin support member being configured to move relative to the susceptor, and
an upper end of one of the abutment portions contacting the predetermined lift pin is located at a position higher than upper ends of the other abutment portions.

5. The wafer transfer device according to claim 2, wherein
the predetermined lift pin is longer than the other lift pins,
the relative movement mechanism comprises a lift-pin support member comprising a plurality of abutment portions contacting respective lower ends of the plurality of lift pins, the lift-pin support member being configured to move relative to the susceptor, and
the upper ends of the plurality of abutment portions are located at the same height position.

6. The wafer transfer device according to claim 1, wherein
at the position above the susceptor, the transport unit is configured to transfer the silicon wafer so that a part of the silicon wafer supported by the predetermined lift pin is located lower than the other part of the silicon wafer.

7. The wafer transfer device according to claim 1, wherein
the transport unit comprises an elongated support member and is configured to transfer the silicon wafer at the position above the susceptor by moving the support member, on which the silicon wafer is mounted, in a longitudinal direction of the support member,
the support member comprises a pair of extensions extending from mutually remote positions in the longitudinal direction of the support member, and
the relative movement mechanism is configured to bring, as the predetermined lift pin, one of the plurality of lift pins located between the pair of extensions into the first contact with the lower side of the silicon wafer.

8. A vapor deposition apparatus configured to form an epitaxial film on a silicon wafer, the vapor deposition apparatus comprising:
a susceptor, on which the silicon wafer is configured to be placed; and
the wafer transfer device according to claim 1, the wafer transfer device being configured to transfer the silicon wafer onto the susceptor.

9. A wafer transfer method for transferring a silicon wafer onto a susceptor of a vapor deposition apparatus configured to form an epitaxial film on the silicon wafer, the wafer transfer method comprising:
a loading step of holding the silicon wafer and transferring the silicon wafer to a position above the susceptor; and
a placing step of placing the silicon wafer transferred in the loading step onto the susceptor, wherein
the placing step comprises relative movement step of raising a plurality of lift pins, which are vertically movably inserted correspondingly one-to-one into a plurality of through holes penetrating through the susceptor, relative to the susceptor to support a lower side of the silicon wafer at the position above the susceptor, and lowering the plurality of lift pins relative to the susceptor to place the silicon wafer onto the susceptor after the silicon wafer is released from the holding in the loading step, and
at least one of the loading step or the placing step comprises bringing a predetermined lift pin of the plurality of lift pins into a first contact with the lower side of the silicon wafer when the silicon wafer is supported by the plurality of lift pins.

10. The wafer transfer method according to claim 9, wherein
a support member, which extends in a longitudinal direction and comprises a pair of extensions extending from mutually remote positions in the longitudinal direction of the support member, is used,
the silicon wafer is of p-type,
the loading step comprises moving the support member carrying the p-type silicon wafer in the longitudinal direction to transfer the p-type silicon wafer to the position above the susceptor, and
in the relative movement step, one of the plurality of lift pins located between the pair of extensions as the predetermined lift pin is brought into the first contact with the lower side of the silicon wafer.

11. A manufacturing method of an epitaxial silicon wafer comprising an epitaxial film formed on a silicon wafer, the manufacturing method comprising:
performing the wafer transfer method for transferring the silicon wafer onto the susceptor according to claim 9; and
vapor-phase growing the epitaxial film on the silicon wafer transferred by the susceptor.
